(19) United States
(12) Patent Application Publication
(10) Pub. No.: US 2023/0134804 A1
(43) Pub. Date: May 4, 2023

(54) DISPLAY DEVICE

(71) Applicant: SHARP KABUSHIKI KAISHA, Sakai City, Osaka (JP)

(72) Inventors: TOHRU SONODA, Sakai City, Osaka (JP); EIJI KOIKE, Sakai City, Osaka (JP)

(21) Appl. No.: 17/912,036

(22) PCT Filed: Mar. 31, 2020
(86) PCT No.: PCT/JP2020/014863

§ 371 Date: Sep. 15, 2022

(51) Int. Cl. H10K 59/122

(52) U.S. Cl. CPC H01L 27/3246; H01L 27/3218

(57) ABSTRACT

A display device includes a thin film transistor layer and a light-emitting element layer in which a plurality of light-emitting elements is formed. Each of the plurality of pixels is provided with a rectangular portion formed in a rectangular shape in a light-emitting region. A long side direction of the rectangular portion is inclined at an angle predetermined with respect to a first direction predetermined in the display region. In pixels of the same luminescent color of the plurality of pixels, the rectangular portions of two pixels adjacent to each other in the first direction or a second direction orthogonal to the first direction are provided at positions rotated by 90° with respect to each other. In the plurality of pixels, a short side of each of the rectangular portions faces the light-emitting region of an adjacent pixel of a different luminescent color.

### TECHNICAL FIELD

The present invention relates to a display device including a display panel in which a pattern including a light-emitting region for emitting light per pixel is provided on a display surface.

### BACKGROUND ART

A conventional display device typically includes (sub) pixels of red color (R), green color (G), and blue color (B) and emit light per subpixel to display information. In such a conventional display device, not only a pixel arrangement of RGB, such as an existing stripe arrangement, but also a new pixel arrangement, such as a PenTile arrangement has been put into practical use (for example, see PTL 1 below).

### CITATION LIST

### Patent Literature

PTL 1: WO 2019/229854 Pamphlet

### SUMMARY OF INVENTION

### Technical Problem

The conventional display device as described above uses, for example, a vapor deposition method to form light-emitting regions of pixels of each color of R, G, and B.

Unfortunately, in the conventional display device, the pixels (light-emitting regions) of each color of R, G, and B are arranged in the PenTile arrangement, the stripe arrangement, or the like, and in a case of, for example, a positional offset of a vapor deposition mask to be used in the vapor deposition method, a color mixing occurrence region where color mixing occurs by a light-emitting material being vapor-deposited on a light-emitting region of another color cannot be reduced, and thus degradation of display quality cannot be prevented.

### Solution to Problem

A display device according to one aspect of the present invention including a display region including a plurality of pixels includes a thin film transistor layer, and a light-emitting element layer in which a plurality of light-emitting elements is formed, the plurality of light-emitting elements including a first electrode, a light-emitting layer, and a second electrode and having a luminescent color different from each other. Each of the plurality of pixels is provided with a rectangular portion formed in a rectangular shape in a light-emitting region, a long side direction of the rectangular portion is inclined at an angle predetermined with respect to a first direction predetermined in the display region. In pixels of the same luminescent color of the plurality of pixels, the rectangular portions of two pixels adjacent to each other in the first direction or a second direction orthogonal to the first direction are provided at positions rotated by 90° with respect to each other, and in the plurality of pixels, a short side of each of the rectangular portions faces the light-emitting region of an adjacent pixel of a different luminescent color.

### Advantageous Effects of Invention

According to an aspect of the present invention, a display device can be provided in which a color mixing occurrence region can be reduced so as to prevent display quality from being reduced even in a case where a light-emitting region of each color is formed by using a vapor deposition method.

### BRIEF DESCRIPTION OF DRAWINGS

FIG. 1 is a plan view illustrating patterns and openings formed in a display region of a display device according to a first embodiment.

FIG. 2 is a cross-sectional view representing a configuration of the display device.

FIG. 3 is an enlarged plan view of the patterns and the openings.

FIG. 4 is an enlarged plan view of a main part for describing details of the openings.

FIG. 5 is an enlarged plan view for describing color mixing when the patterns are formed offset.

FIG. 6 is an enlarged plan view for describing penetration of the patterns into other color pixels at the time of the color mixing.

FIG. 7 is an enlarged plan view of patterns according to a comparative example.

FIG. 8 is an enlarged plan view for describing penetration of the patterns according to the comparative example into other color pixels at the time of color mixing.

FIG. 9 is a plan view illustrating patterns and openings formed in a display region of a display device according to a second embodiment.

FIG. 10 is an enlarged plan view of a main part for describing details of an opening.

FIG. 11 is a plan view illustrating patterns and openings formed in a display region of a display device according to a third embodiment.

FIG. 12 is an enlarged plan view of a main part for describing details of the openings.

FIG. 13 is a plan view illustrating patterns and openings formed in a display region of a display device according to a fourth embodiment.

FIG. 14 is an enlarged plan view of a main part for describing details of the opening.

### DESCRIPTION OF EMBODIMENTS

### First Embodiment

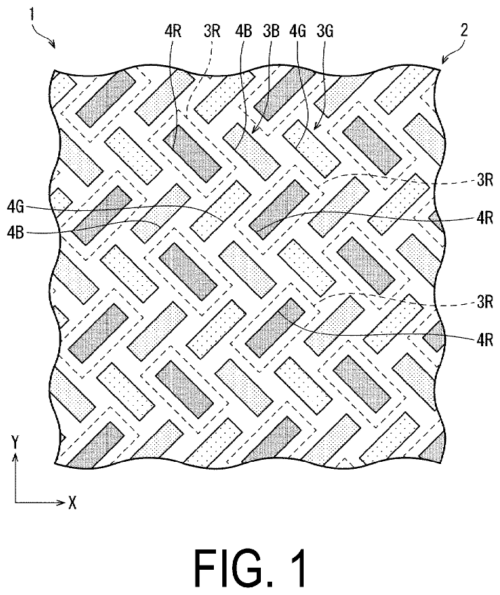

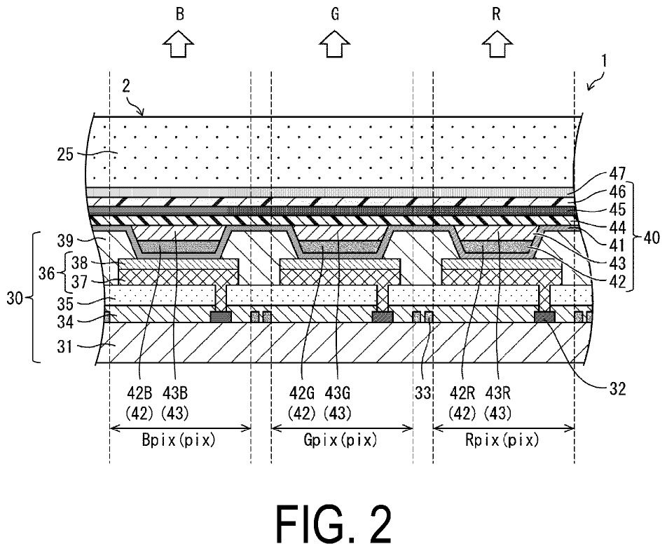

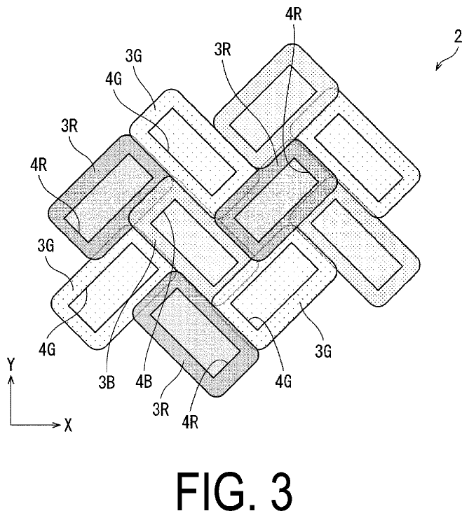

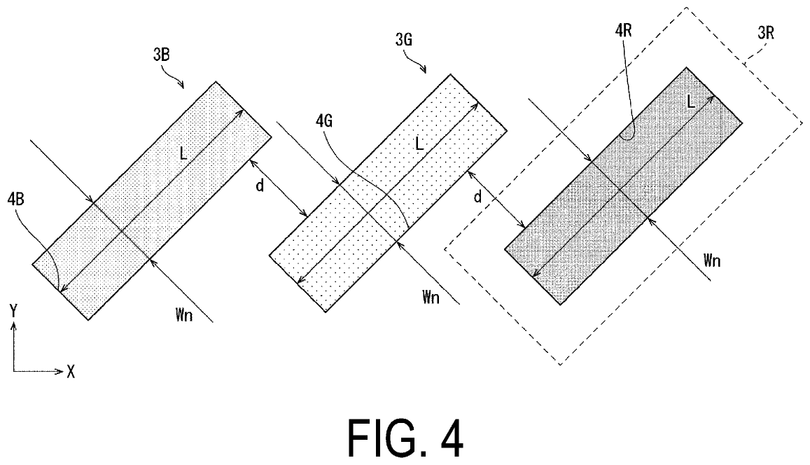

FIG. 1 is a plan view illustrating a first pattern 3R, a second pattern 3G, a third pattern 3B, a first opening 4R, a second opening 4G, and a third opening 4B formed in a display region 2 of a display device 1 according to a first embodiment. FIG. 2 is a cross-sectional view representing a configuration of the display device 1. FIG. 3 is an enlarged plan view of the patterns and the openings. FIG. 4 is an enlarged plan view of a main part for describing details of the first opening 4R, the second opening 4G, and the third opening 4B.

The display device 1 includes the display region 2 including a plurality of red pixels Rpix (red color pixels), green pixels Gpix (green color pixels), and blue pixels Bpix (blue color pixels). An Organic Light Emitting Diode (OLED), which constitutes a pixel for displaying an image, is provided in the display region 2.

The display device 1 includes a Thin Film Transistor (TFT) substrate 30. The TFT substrate 30 is prepared by forming, on a light-transmitting support substrate 31 such as mother glass, a resin layer (not illustrated) and a barrier layer (not illustrated), forming, on the layers, a TFT 32 (a thin film transistor layer) included in a pixel circuit provided on each pixel pix and various types of wiring lines 33 including a gate wiring line and a source wiring line by a known method, forming a passivation film (protection film) 34, an interlayer insulating film (flattening film) 35, and the like, and further forming, on the interlayer insulating film 35,

an anode electrode (a reflective electrode layer) 36 being in contact with an anode and a pixel bank 39 for defining a ITO layer and a light-emitting region.

Examples of the material of the resin layer (not illustrated) include polyimide, epoxy, and polyamide.

The barrier layer (not illustrated) is a layer that inhibits moisture and impurities from reaching the TFT 32 and an EL layer 40 (light-emitting element layer) when the display device 1 is used and can be formed by a silicon oxide film, a silicon nitride film, a silicon oxynitride film, or a layered film thereof formed by, for example, chemical vapor deposition (CVD).

The TFT 32 is a drive transistor for supplying a drive current to the EL layer 40. While not illustrated, the TFT 32 has a semiconductor layer, a gate electrode, a drain electrode, and a source electrode.

The passivation film 34 is formed so as to cover the TFT 32. Thus, the passivation film 34 prevents peeling of a metal film in the TFT 32 and protects the TFT 32. The passivation film 34 is an inorganic insulating film made of silicon nitride, silicon oxide, or the like.

The interlayer insulating film 35 is formed on the passivation film 34. The interlayer insulating film 35 is a flattening film for leveling irregularities on the passivation film 34. The interlayer insulating film 35 is an organic insulating film including a photosensitive resin such as acrylic and polyimide.

An anode electrode 36 (first electrode) is individually patterned in an island shape for each pixel pix, with an end portion of the anode electrode 36 covered by the pixel bank 39. Each anode electrode 36 is connected to the TFT 32 via a contact hole provided in the passivation film 34 and the interlayer insulating film 35.

The anode electrode 36 functions as an electrode for injecting holes into the EL layer 40. Further, in the present embodiment, the anode 36 has a structure in which a light-transmissive electrode 38 is laminated on a reflective film 37. Note that the anode electrode 36 may be a single layer structure including the reflective film 37 or may be layered with other layers other than the light-transmissive electrode 38.

Examples of materials of the reflective film 37 include, for example, a black electrode material such as tantalum (Ta) or Carbon®, a reflective metal electrode material such as Al, Ag, gold (Au), Al—Li alloy, Al-neodymium (Nd) alloy, alloy containing Ag, or Al-silicon (Si) alloy.

As examples of materials of the light-transmissive electrode 38 include, for example, a transparent electrode material such as indium tin oxide (ITO), tin oxide (SnO₂), indium zinc oxide (IZO), gallium-added and zinc oxide (GZO) may be utilized, and a semitransparent electrode material such as a thin film of Ag may be utilized.

The pixel bank 39 (edge cover film) is disposed so as to partition the pixels adjacent to each other. The pixel bank 39 is an insulating layer, and is made, for example, from a photosensitive resin. The pixel bank 39 is formed to cover an edge of the anode electrode 36 and define the light-emitting region by an opening. The pixel bank 39 functions as an edge cover that prevents short circuiting between the end of the anode electrode 36 and

a cathode electrode 47 even when the end of the EL layer 40 is thin. In addition, the pixel bank 39 functions also as a pixel separation film configured to prevent electric current from leaking out from one pixel pix to an adjacent pixel pix.

In addition, at the time of forming an active area, a frame-shaped bank (not illustrated)) surrounding the active area in a frame-like shape is also formed on the TFT substrate 30. The frame-shaped bank includes a photosensitive resin such as an acrylic or a polyimide.

The EL layer 40 and the cathode electrode 47 (second electrode) are formed on the TFT substrate 30.

For example, a hole injection layer 41, a hole transport layer 42, a light-emitting layer 43, a hole shielding layer 44, and an electron transport layer 45 and an electron injection layer 46 are layered on the TFT substrate 30 in this order from the anode electrode 36 side by vapor deposition or the like. In this way, the EL layer 40 is formed on the TFT substrate 30. The cathode electrode 47 is formed so as to cover the EL layer 40 formed on the TFT substrate 30.

The hole transport layer 42 and the light-emitting layer 43 are formed in the island shape for each pixel pix by vapor deposition using a vapor deposition mask, and the hole injection layer 41, the hole shielding layer 44, the electron transport layer 45, the electron injection layer 46, and the cathode electrode 47 are each configured in a solid-like common layer formed across a plurality of the pixels pix, as illustrated in the drawings. Further, it is also possible to adopt a configuration in which one or more layers of the hole injection layer 41, the hole shielding layer 44, the electron transport layer 45, and the electron injection layer 46 are not formed.

Note that a layer vapor-deposited for each pixel pix by using the vapor deposition mask, such as the hole transport layer 42 and the light-emitting layer 43, is referred to as a deposition layer.

The cathode electrode 47 is constituted by a light-transmitting conductive material such as Indium Tin Oxide (ITO) and Indium Zinc Oxide (IZO) or a semitransparent conductive material formed of Ag or Mg.

The light-emitting layer 43 and the hole transport layer 42 are formed on the pixel pix for each luminescent color of the pixel pix. For example, in a case where the pixel pix is any of the red pixel Rpix that emits red light, the green pixel Gpix that emits green light, and the blue pixel Bpix that emits blue light, a red light-emitting layer 43R and a red hole transport layer 42R are formed in the red pixel Rpix, a green light-emitting layer 43G and a green hole transport layer 42G are formed in the green pixel Gpix, and a blue light-emitting layer 43B and a blue hole transport layer 42B are formed in the blue pixel Bpix.

The hole injection layer 41 includes a hole injection material and has a function to increase the efficiency of injecting a hole into the light-emitting layer 43.

The hole transport layer 42 includes a hole transport material and has a function to enhance the efficiency of transporting a positive hole, which is injected from the anode electrode 36 and transported via the hole injection layer 41, into light-emitting layer 43. The red hole transport layer 42R increases the efficiency of transporting a positive hole to the red light-emitting layer 43R, the green hole transport layer 42G increases the efficiency of transporting a positive hole to the green light-emitting layer 43G, and the blue hole transport layer 42B increases the efficiency of transporting a positive hole to the blue light-emitting layer 43B.

The hole shielding layer 44 includes a material preventing movement of the positive hole and prevents the positive hole from being transported to the electron transport layer 45 through the light-emitting layer 43.

The electron injection layer 46 includes an electron injection material and has a function to increase the efficiency of injecting an electron into the light-emitting layer 43. The electron transport layer 45 includes an electron transport material and has a function to increase the efficiency of transporting an electron to the light-emitting layer 43.

A positive hole injected from the anode electrode 36 into the light-emitting layer 43 and an electron injected from the cathode electrode 47 into the light-emitting layer 43 are recombined in the light-emitting layer 43 to form an exciton. The formed exciton emits light when deactivated from the excited state to the ground state. As a result, the red light-emitting layer 43R emits red light, the green light-emitting layer 43G emits green light, and the blue light-emitting layer 43B emits blue light.

The red hole transport layer 42R, the red light-emitting layer 43R, the green hole transport layer 42G, the green light-emitting layer 43G, the blue hole transport layer 42B, and the blue light-emitting layer 43B are each formed on the pixel pix sequentially by using the vapor deposition mask in a vapor deposition step. The vapor deposition mask used in the vapor deposition step is prepared for each luminescent color before the vapor deposition step.

The layer formed by using the vapor deposition mask is not limited to the hole transport layer 42 and the light-emitting layer 43 and may be any layer formed for each pixel pix (namely, in the opening of the pixel bank 39).

Although the case where the light-emitting element layer including the anode 36, the EL layer 40, and the cathode 47 constitutes the OLED element is described, the light-emitting element layer is not limited to the case to constitute the OLED element and may constitute an inorganic light-emitting diode or a quantum dot light-emitting diode.

Then a sealing layer 25 is formed on the cathode electrode 47. As an example, the sealing layer 25 can include a three layer structure in which an inorganic film, an organic film, and an inorganic film are layered in this order from the TFT substrate 30 side. Since the frame-shaped bank (not illustrated) is formed, the organic film can be formed to have a large thickness of, for example, 5 μm or greater.

A plurality of first patterns 3R formed in the display region 2 is disposed in the plurality of red pixels Rpix to include a light-emitting region including a first opening 4R (rectangular portion) formed in a rectangular shape in a plan view to emit red light. A plurality of the second patterns 3G formed in the display region 2 is disposed in the plurality of green pixels Gpix to include a light-emitting region including a second opening 4G (rectangular portion) formed in a rectangular shape to emit green light. A plurality of the third patterns 3B formed in the display region 2 is disposed in the plurality of blue pixels Bpix to include a light-emitting region including a third opening 4B (rectangular portion) formed in a rectangular shape to emit blue light.

The first opening 4R, the second opening 4G, and the third opening 4B are arranged along a direction inclined at a predetermined angle with respect to an X direction (lateral direction, first direction) in a plan view. This predetermined angle is, for example, approximately 45° or approximately 135°.

The first openings 4R of the two red pixels Rpix adjacent to each other in the X direction or the Y direction are provided at positions rotated by 90° from each other. The first openings 4G of the two green pixels Gpix adjacent to each other in the X direction or the Y direction are also provided at positions rotated by 90° from each other, and the first openings 4B of the two blue pixels Bpix adjacent to each other are also provided at positions rotated by 90° from each other.

One short side of the first opening 4R of the red pixel Rpix faces a long side of the second opening 4G of the adjacent green pixel Gpix, and the other short side faces a long side of the third opening 4B of the adjacent blue pixel Bpix. Then, one short side of the first opening 4G of the green pixel Gpix faces a long side of the third opening 4B of the adjacent blue pixel Bpix, and the other short side faces a long side of the first opening 4R of the adjacent red pixel Rpix. One short side of the third opening 4B of the blue pixel Bpix faces a long side of the first opening 4R of the adjacent red pixel Rpix, and the other short side faces a long side of the second opening 4G of adjacent the green pixel Gpix.

The pixel bank 39 covers the edge of the anode electrode 36 and defines the light-emitting region by the first opening 4R, the second opening 4G, and the third opening 4B.

However, the predetermined angle is not limited to approximately 45° or approximately 135° and may be, for example, 30° or 60° with respect to the X direction, and the adjacent pixels of the same color may have a relationship in which the rectangular portions are rotated by 90°.

The first opening 4R, the second opening 4G, and the third opening 4B are formed in a rectangular shape in a plan view and are arranged in a staggered shape in which rectangles are obliquely displaced and regularly arranged in the vertical and horizontal directions.

Aspect ratios of the first opening 4R, the second opening 4G, and the third opening 4B are preferably 2:1 or greater.

The first pattern 3R, the second pattern 3G, and the third pattern 3B are also formed in a rectangular shape in a plan view, arranged along a direction inclined at 45° or 135° with respect to the X direction, and arranged in the staggered shape in which the rectangles are obliquely displaced and regularly arranged in the vertical and horizontal directions.

In the first embodiment, the opening ratio of each of the R, G, and B pixels is approximately 1:1:1.

As illustrated in FIG. 4, in the first embodiment, an aperture ratio NA of each of R, G, and B is L×Wn/(L+d)(Wn+d) where d is a dimension (distance between openings in the edge cover (color separation)) obtained by subtracting a dimension Wn of the first opening 3R in the short side direction from a length of the first pattern 4R in the short side direction, L is a dimension of a longitudinal opening width of each of the first opening 4R, the second opening 4G, and the third opening 4B, and Wn is a dimension of a lateral opening width of each of the first opening 4R, the second opening 4G, and the third opening 4B. Where, L+d:Wn+d=2:1. At this time,

L/Wn=2+d/Wn>2. (Relationship 1), and

L/Wn (aspect ratio of the opening) is greater than 2.

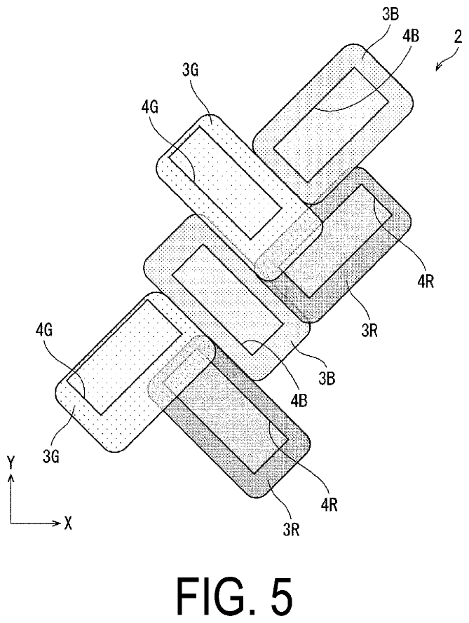

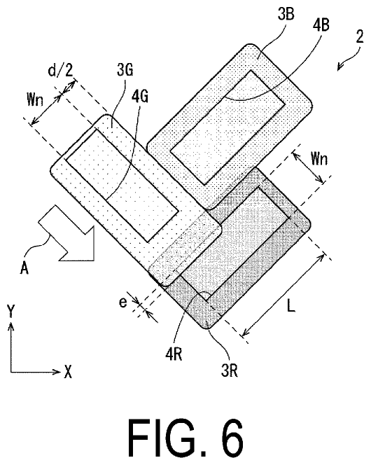

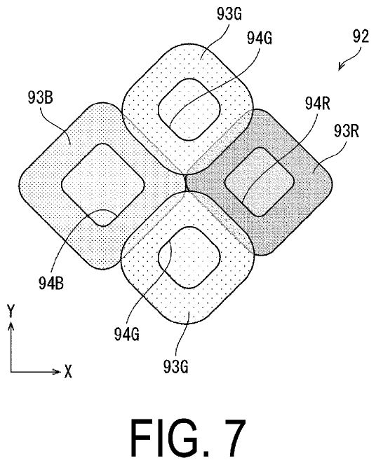

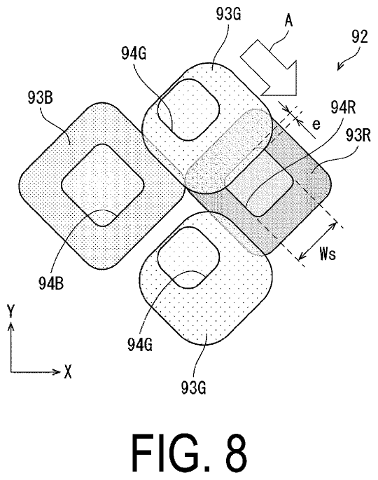

FIG. 5 is an enlarged plan view for describing color mixing when the first pattern 3R, the second pattern 3G, and the third pattern 3B are formed offset. FIG. 6 is an enlarged plan view for describing penetration of the first pattern 3R, the second pattern 3G, and the third pattern 3B into other color pixels at the time of the color mixing. FIG. 7 is an enlarged plan view of a first pattern 93R, a second pattern 93G, and a third pattern 93B according to a comparative example. FIG. 8 is an enlarged plan view for describing penetration of the first pattern 93R, the second pattern 93G, and the third pattern 93B according to the comparative example into other color pixels at the time of the color mixing.

The first pattern 93R, the second pattern 93G, and the third pattern 93B, and the first opening 94R, the second opening 94G, and the third opening 94B are formed in a substantially square shape. FIG. 7 illustrates an ideal state in which there is no positional offset of film formations of the first pattern 93R, the second pattern 93G, and the third pattern 93B. As illustrated in FIG. 8, when the film formation position of the second pattern 93G according to the comparative example is offset along the direction indicated by an arrow A inclined at 1350 with respect to the X direction, the second pattern 93G intrudes into the first opening 94R of the first pattern 93R by an intrusion amount e. This causes the color mixing between the second pattern 93G of green color and the first opening 94R of red color, which is another color. Thus, a color mixing occurrence region indicating the degree of the second pattern 93G intruding into the first opening 94R of the first pattern 93R appears.

In contrast, the first pattern 3R, the second pattern 3G, the third pattern 3B, the first opening 4R, the second opening 4G, and the third opening 4B according to the first embodiment are arranged in the staggered shape in which the rectangles are obliquely offset and regularly arranged in the vertical and horizontal directions. Thus, as illustrated in FIGS. 5 and 6, even when the film formation position of the second pattern 3G is offset by the intrusion amount e along the direction indicated by the arrow A inclined at 135° with respect to the X direction, an area of the color mixing occurrence region indicating the degree of intrusion of the second pattern 3G into the first opening 4R of the first pattern 3R is smaller than an area of the color mixing occurrence region according to the comparative example in FIG. 8. Accordingly, the color mixing occurrence region can be reduced, and the display quality of the display device 1 can be improved.

Assuming that the structure of the comparative example illustrated in FIG. 8 has a higher color mixing area ratio at the time of color mixing (at the time of pattern offset) than the structure of the embodiment illustrated in FIG. 6, the edge of the long side of the opening of the pattern on the side to intrude is present on the same straight line as the edge of the short side of the opening of the pattern on the side to be intruded, and a relationship

e×Ws/Ws²>e×(Wn+d/2)/(Wn×L)

is established where e is an intrusion amount of a pattern into an opening of an adjacent pattern, Ws is a dimension of an opening according to the comparative example, L is the longitudinal opening width of the first opening 4R, the second opening 4G, and the third opening 4B, and Wn is the lateral opening width of the first opening 4R, the second opening 4G, and the third opening 4B.

Here, in a case where the opening areas are matched between the structure of the comparative example and the structure of the embodiment, Ws²=(Wn×L) is established, and

Ws>Wn+d/2 . . . is satisfied.

When both sides of the above relationship are squared and transformed (using Ws²=(Wn×L)),

Wn×L>Wn²+Wn×d+d²/4 is obtained,

when both sides of the above relationship are divided by Wn² and (Relationship 1) described in the first embodiment is used 2+d/Wn>1+d/Wn+d²/4Wn² is obtained, and the following is finally obtained.

Wn>d/2 (Relationship 2). When the condition of (Relationship 2) is satisfied, the color mixing area at the time of color mixing is relatively smaller in the structure of the embodiment than in the structure of the comparative example.

Here, the dimension L of the longitudinal opening width is 29.3 μm, for example, and the dimension Wn of the lateral opening width is 7.7 μm, for example. The dimension d is 14 μm, for example.

The dimension Ws is 15 μm, for example. The aperture ratio of each opening according to the comparative example matches the aperture ratio of a corresponding opening according to the embodiment. In other words, Ws²=L×Wn. The intrusion amount e is 3 μm, for example.

An actual product of the display device 1 is affected by a variation in the manufacturing process, and the vapor deposition (film formation) pattern is finished variously offset to a greater or lesser extent. Thus, in a case where the color mixing is large (in a case where the positional offset of the film formation is large), the pattern is defective and the yield is lowered. In addition, in a case where the color mixing is small (in a case where the positional offset of the film formation is small), a color unevenness is formed to be present in the product of the display device 1.

Here, although the color unevenness can be corrected in the manufacturing process (color unevenness correction), the color unevenness that is not corrected remains in the product within a range determined to be good quality. Accordingly, the structure of the present embodiment in which the ratio of the color mixing area is reduced leads to a reduction in the color unevenness thereof and can improve the display quality of the product itself of the display device 1.

Furthermore, even when the color unevenness correction is completely performed, in a case where, for example, the green color pattern is mixed into a blue color pattern, luminance of blue color in which the light emission area is reduced is increased by the color unevenness correction process. Thus, although the color unevenness is corrected, luminance service life of the pixel with increased luminance is reduced due to voltage rise and current density increase.

Thus, the greater the color unevenness correction, the lower the luminance reduction (and luminance variation for each pixel) of the display device 1 in long-term use, and thus the smaller the ratio of the color mixing area is to improve the reliability of the display device 1.

As a result of the above, it is possible to prove that the problem is solved by the present embodiment from the viewpoint of the display quality and reliability of the display device 1.

### Second Embodiment

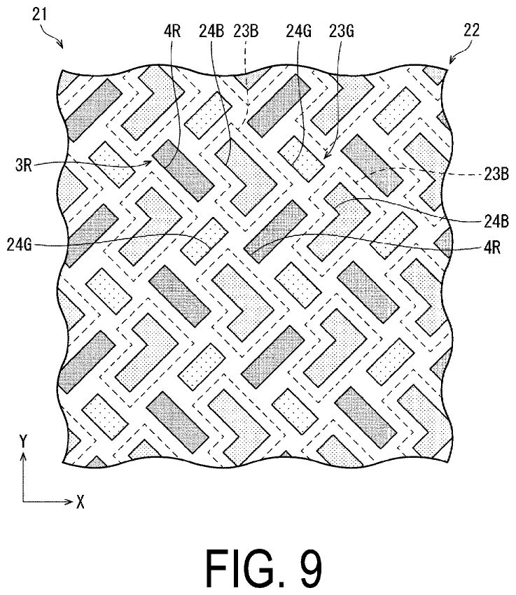

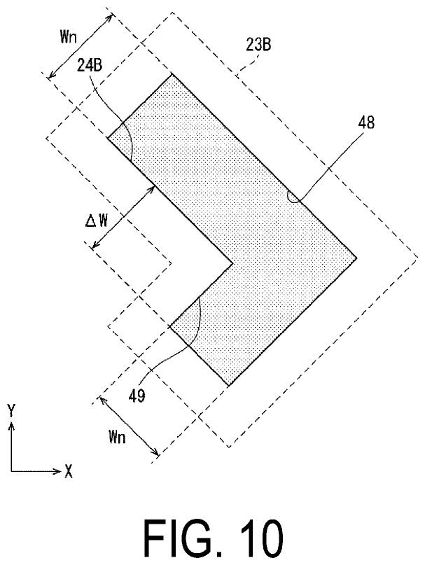

FIG. 9 is a plan view illustrating patterns and openings formed in a display region 22 of a display device 21 according to a second embodiment. FIG. 10 is an enlarged plan view of a main part for describing details of a third opening 24B. Constituent elements similar to the constituent elements described above are given the same reference numerals, and detailed descriptions thereof are not repeated.

The display device 21 includes the display region 22. The plurality of first pattern 3R having a rectangular shape is disposed in the plurality of red pixels Rpix. A plurality of second pattern 23G having a rectangular shape is disposed in the plurality of green pixels Gpix. Then, a plurality of third patterns 23B having an L shape formed in the display region 22 is disposed in the plurality of the blue pixel Bpix to include a light-emitting region including the third opening 24B formed in the L shape to emit blue light.

In this manner, the blue pixel Bpix is provided with the light-emitting region having the L shape formed of the third opening 24B. The third opening 24B having the L shape includes a base portion 48 (rectangular portion) formed in a rectangular shape and a protrusion 49 protruding from one short side in the orthogonal direction orthogonal to a long side of the base portion 48.

A protruding length ΔW of the protrusion 49 is a value in a range from 0.1 times to 2 times the dimension Wn of the short side of the base portion 48. In a case of 0.1 times or more, display quality of the display device 1 is improved. In a case of two times or less, color mixing caused by deposition of the light-emitting material on a light-emitting region of another color is prevented.

The third opening 24B having the L shape of the blue pixel Bpix has a shape in which a third opening 24B having the L shape of the blue pixel Bpix adjacent to the third opening 24B having the L shape in the X direction or the Y direction is rotated by 90° and is mirror inverted so as to be line-symmetric with respect to a central axis along the long side of the base portion 48.

The third pattern 23B and the third opening 24B are formed in the L shape in a plan view with respect to the display region 2. The base portion 48 of the third opening 24B extends along an inclination direction in which the extending direction of at least one of the base portions 48 of the adjacent third openings 24B is rotated by 90°.

The first opening 4R and a second opening 24G are formed in a rectangular shape in a plan view. The first opening 4R, the second opening 24G, and the third opening 24B are formed in a pattern shape in which the rectangular and the L shapes are obliquely displaced and regularly arranged in the vertical and horizontal directions.

In the second embodiment, the opening ratio of each of the R, G, and B pixels is X:Y:Z (Y<X<Z).

Then in the second embodiment, the aperture ratio NA of each luminescent color is NA®=L×Wn/(L+d)(Wn+d), NA(G)=(L−ΔW)×Wn/(L+d)(Wn+d), and NA(B)=(L+ΔW)×Wn/(L+d)(Wn+d).

Note that in the above description, the case is described in which the width dimension of the base portion 48 on the short side and the width dimension of the protrusion 49 are set to the same value, but the present embodiment is not limited thereto, and the values may be different values from each other.

### Third Embodiment

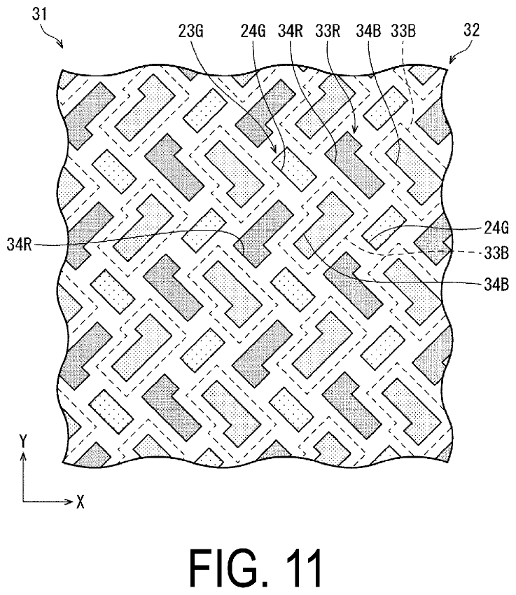

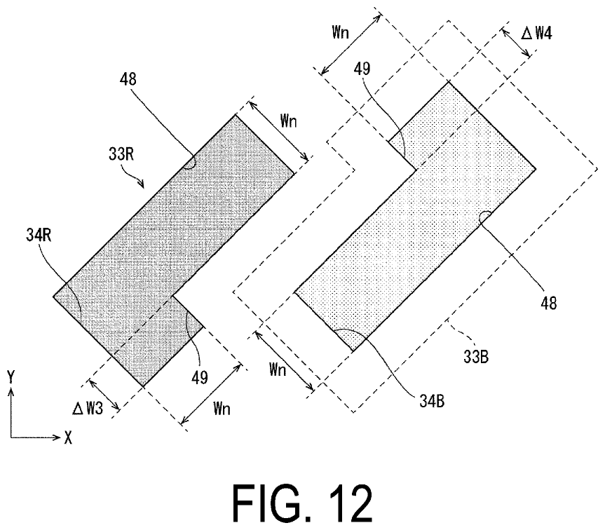

FIG. 11 is a plan view illustrating patterns and openings formed in a display region 32 of a display device 31 according to a third embodiment. FIG. 12 is an enlarged plan view of a main part for describing details of the openings. Constituent elements similar to the constituent elements described above are given the same reference numerals, and detailed descriptions thereof are not repeated.

The display device 31 includes the display region 32. A plurality of the first patterns 33R having the L shape formed in the display region 32 is disposed in the plurality of red pixels Rpix to include a light-emitting region including a first opening 34R formed in the L shape. Then, a plurality of the third patterns 33B having the L shape formed in the display region 32 is disposed in the plurality of blue pixels Bpix to include a light-emitting region including a third opening 34B formed in the L shape. A second opening 24G having a rectangular shape is disposed in each of the plurality of green pixels Gpix.

In this manner, the red pixel Rpix and blue pixel Bpix of the red pixel Rpix, green pixel Gpix, and blue pixel Bpix are respectively provided with the first opening 34R and the third opening 34B of the light-emitting regions having the L shape.

The first opening 34R and the third opening 34B of the light-emitting regions having the L shape in the pixels of two luminescent colors have the same dimensions of protruding lengths ΔW3 and ΔW4 of the protrusion 49 (protruding dimensions). The protruding lengths ΔW3 and ΔW4 of the protrusion 49 are values in a range from 0.1 times to 2 times the dimension Wn of the short side of the base portion 48.

The third opening 34B having the L shape of the blue pixel Bpix has a shape in which a third opening 34B having the L shape of the blue pixel Bpix adjacent to the third opening 34B having the L shape in the X direction or the Y direction is rotated by 90° and is mirror inverted so as to be line-symmetric with respect to a central axis along the long side of the base portion 48. The first opening 34R having the L shape of the red pixel Rpix also has a shape in which a first opening 34R having the L shape of the red pixel Rpix adjacent to the first opening 34R having the L shape in the X direction or the Y direction is rotated by 90° and is mirror inverted so as to be line-symmetric with respect to a central axis along the long side of the base portion 48.

The third opening 34B formed in the L shape includes, for example, a base portion 48 that extends along a direction inclined at 45° with respect to the X direction in a plan view, and a protrusion 49 that protrudes by a dimension ΔW4 from one end of the base portion 48 toward a direction inclined at 135° with respect to the X direction. The first opening 34R also includes a similar base 48 and a similar protrusion 49.

The first pattern 33R, the first opening 34R, the third pattern 33B and the third opening 34B are formed in the L shape in a plan view with respect to the display region 2. The base portion 48 of the first opening 34R extends along an inclination direction in which the extending direction of at least one of the base portions 48 of the adjacent first openings 34R is rotated by 90°. The base portion 48 of the third opening 34B extends along an inclination direction in which the extending direction of at least one of the base portions 48 of the adjacent third openings 34B is rotated by 90°.

The second opening 24G is formed in a rectangular shape in a plan view. The first opening 34R, the second opening 24G, and the third opening 34B are formed in a pattern shape in which the rectangular and the L shapes are obliquely displaced and regularly arranged in the vertical and horizontal directions.

In the third embodiment, in a case of ΔW3=ΔW4=AW, the opening ratio of each of the R, G, and B pixels is X:Y:X (Y<X).

In the third embodiment, the aperture ratio NA of each luminescent color is NA®=(L+ΔW3)×Wn/(L+d)(Wn+d), NA(G)=(L−ΔW3−ΔW4)×Wn/(L+d). (Wn+d), and NA(B)=(L+ΔW4)×Wn/(L+d)(Wn+d).

Note that in the above description, the case is described in which the width dimension of the base portion 48 on the short side and the width dimension of the protrusion 49 are set to the same value, but the present embodiment is not limited thereto, and the values may be different values from each other.

### Fourth Embodiment

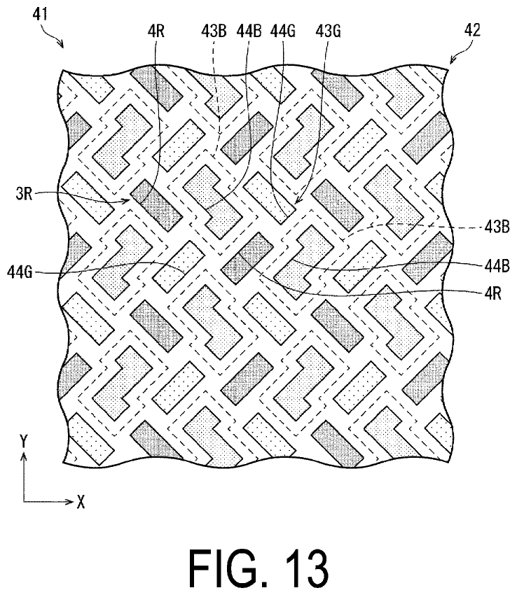

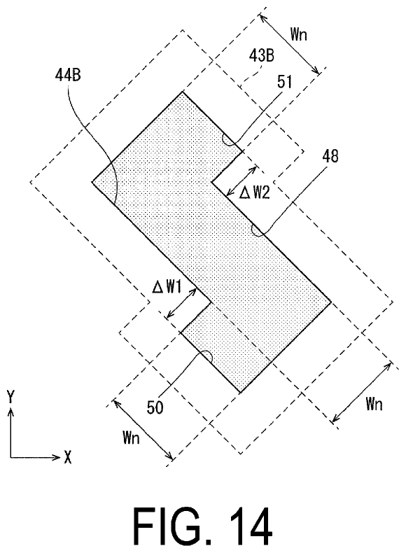

FIG. 13 is a plan view illustrating patterns and openings formed in a display region 42 of a display device 41 according to a fourth embodiment. FIG. 14 is an enlarged plan view of a main part for describing details of the opening. Constituent elements similar to the constituent elements described above are given the same reference numerals, and detailed descriptions thereof are not repeated.

The display device 41 includes the display region 42. Each of the plurality of the blue pixels Bpix is provided with the light-emitting region including the third opening 44B formed in an S shape.

The third opening 44B having the S shape includes a base portion 48 (rectangular portion) formed in a rectangular shape, a first protrusion 50 protruding from one short side in one orthogonal direction of orthogonal directions orthogonal to a long side of the base portion 48, and a second protrusion 51 protruding from the other short side in the other orthogonal direction of the orthogonal directions orthogonal to the long side of the base portion 48.

The third opening 44B having the S shape has a shape in which a third opening 44B having the S shape of the blue pixel Bpix having the S shape adjacent in the X direction or the Y direction is rotated by 90° and is mirror inverted so as to be line-symmetric with respect to a central axis along the long side of the base portion 48.

A protruding length ΔW1 of the first protrusion 50 and a protruding length ΔW2 of the second protrusion 51 are values in a range from 0.1 times to 2 times the dimension Wn of the short side length of the short side of the base portion 48.

The protruding length ΔW1 of the first protrusion 50 and the protruding length ΔW2 of the second protrusion 51 are the same.

The display device 41 includes first patterns 3R having a rectangular shape including a first opening 4R formed in a rectangular shape, second patterns 43G having a rectangular shape including a second opening 44G formed in a rectangular shape, and a plurality of third patterns 43B having a substantially S shape formed on the display region 42 to include a third opening 44B formed in a substantially S shape.

The first opening 4R and the second opening 44G formed in a rectangular shape are arranged along a direction inclined at 45° or 135° with respect to the X direction in a plan view.

The base portion 48 of the third opening 44B formed in the substantially S shape is arranged along an inclination direction in which an inclination direction of at least one of the base portions 48 of the adjacent third openings 44B is rotated by 90°. The first opening 4R formed in a rectangular shape is arranged along an inclination direction in which an inclination direction of at least one of the adjacent first openings 4R is rotated by 90°. The second opening 44G is also arranged along an inclination direction in which an inclination direction of at least one of the adjacent second openings 44G is rotated by 90°.

The first opening 4R, the second opening 44G, and the third opening 44B are formed in a pattern shape in which the rectangular and the substantially S shapes are obliquely displaced and regularly arranged in the vertical and horizontal directions.

In the fourth embodiment, in a case of ΔW1=ΔW2=AW, the opening ratio of each of the R, G, and B pixels is X:X:Y (X<Y).

In the fourth embodiment, the aperture ratio NA of each luminescent color is NA®=(L+ΔW2)×Wn/(L+d)(Wn+d), NA(G)=(L−ΔW1)×Wn/(L+d). (Wn+d), and NA(B)=(L+ΔW1+ΔW2)×Wn/(L+d)(Wn+d).

Additionally, in the second embodiment illustrated in FIG. 9, the third embodiment illustrated in FIG. 11, and the fourth embodiment illustrated in FIG. 13, the protruding length ΔW of the third opening 24B having the L shape, the protruding length ΔW3 of the first opening 34R having the L shape, the protruding length ΔW4 of the third opening 34B having the L shape, and the first protruding length ΔW1 and the second protruding length ΔW2 of the third opening 44B are each made different, and thus the ratio of any aperture ratio NA for each luminescent color can be obtained.

The present invention is not limited to each of the embodiments described above, and various modifications may be made within the scope of the claims. Embodiments obtained by appropriately combining technical approaches disclosed in each of the different embodiments also fall within the technical scope of the present invention. Furthermore, novel technical features can be formed by combining the technical approaches disclosed in each of the embodiments.

### REFERENCE SIGNS LIST

1 Display device
2 Display region
3R First pattern
3G Second pattern
3B Third pattern
4R First opening (rectangular portion, light-emitting region)
4G Second opening (rectangular portion, light-emitting region)
4B Third opening (rectangular portion, light-emitting region)
32 TFT (thin film transistor layer)
36 Anode electrode (first electrode)
39 Pixel bank (edge cover film)
40 EL layer (light-emitting element layer)
43 Light-emitting layer
47 Cathode electrode (second electrode)
48 Base portion (rectangular portion)
49 Protrusion
50 First protrusion
51 Second protrusion
ΔW Protruding length (protruding dimension)
ΔW1 First protruding length
ΔW2 Second protruding length
ΔW3 Protruding length
ΔW4 Protruding length
L Dimension
Wn Dimension
Rpix Red pixel (red color pixel)
Gpix Green pixel (green color pixel)
Bpix Blue pixel (blue color pixel)

1. A display device including a display region including a plurality of pixels comprising:
a thin film transistor layer; and
a light-emitting element layer in which a plurality of light-emitting elements is formed, the plurality of light-emitting elements including a first electrode, a light-emitting layer, and a second electrode and having a luminescent color different from each other,
wherein each of the plurality of pixels is provided with a rectangular portion formed in a rectangular shape in a light-emitting region, a long side direction of the rectangular portion is inclined at an angle predetermined with respect to a first direction predetermined in the display region,
in pixels of the same luminescent color of the plurality of pixels, the rectangular portions of two pixels adjacent to each other in the first direction or a second direction orthogonal to the first direction are provided at positions rotated by 90° with respect to each other, and
in the plurality of pixels, a short side of each of the rectangular portions faces the light-emitting region of an adjacent pixel of a different luminescent color.

2. The display device according to claim 1,
wherein the first direction includes one and the other of longitudinal directions of the display region, the second direction includes one and the other of lateral directions of the display region, and
the angle is 45°.

3. The display device according to claim 1, further comprising:
an edge cover film configured to cover an edge of the first electrode and define the light-emitting region by using an opening,
wherein the rectangular portion satisfies the following relationship
Wn>d/2
where Wn is a length of a short side of the rectangular portion, and d is a distance between two of the openings adjacent to each other.

4. The display device according to claim 1,
wherein pixels of at least one luminescent color of the plurality of pixels are provided with a light-emitting region having an L shape, and
the light-emitting region having the L shape rotated by 90° is line-symmetric with respect to a light-emitting region having the L shape of a pixel adjacent in the first direction or the second direction.

5. The display device according to claim 4,
wherein the light-emitting region having the L shape includes the rectangular portion, and a protrusion protruding from one short side in an orthogonal direction orthogonal to a long side of the rectangular portion.

6. The display device according to claim 5,
wherein a protruding length of the protrusion is a value in a range from 0.1 times to 2 times the length of a short side of the rectangular portion.

7. The display device according to claim 6,
wherein pixels of two luminescent colors of the plurality of pixels are each provided with the light-emitting region having the L shape, and
in the light-emitting regions having the L shape in the pixels of the two luminescent colors, protruding dimensions of the protrusions are the same.

8. The display device according to claim 7,
wherein in the light-emitting regions having the L shape in the pixels of the two luminescent colors, a total dimension of protruding dimensions of the two protrusions is identical to a width dimension of each of the two protrusions.

9. The display device according to claim 1,
wherein pixels of at least one luminescent color of the plurality of pixels are provided with a light-emitting region having an S shape, and
the light-emitting region having the S shape rotated by 90° is line-symmetric with respect to a light-emitting region having the S shape of a pixel adjacent in the first direction or the second direction.

10. The display device according to claim 9,
wherein the light-emitting region having the S shape includes the rectangular portion, a first protrusion protruding from one short side in one orthogonal direction of orthogonal directions orthogonal to a long side of the rectangular portion, and a second protrusion protruding from the other short side in the other orthogonal direction of the orthogonal directions orthogonal to the long side of the rectangular portion.

11. The display device according to claim 10,
wherein each of protruding lengths of the first protrusion and the second protrusion is a value in a range from 0.1 times to 2 times the length of a short side of the rectangular portion.

12. The display device according to claim 10,
wherein the protruding length of the first protrusion and the protruding length of the second protrusion are the same.

13. The display device according to claim 1,
wherein the plurality of pixels includes red pixels configured to emit red light, green pixels configured to emit green light, and blue pixels configured to emit blue light.
